(19) United States
(12) Patent Application Publication
(10) Pub. No.: US 2013/0294137 A1
(43) Pub. Date: Nov. 7, 2013

(54) SEMICONDUCTOR DEVICE HAVING BIT LINE HIERARCHICALLY STRUCTURED

(71) Applicant: ELPIDA MEMORY, INC., Tokyo (JP)

(72) Inventors: Noriaki MOCHIDA, Tokyo (JP); Hiroyuki UNO, Tokyo (JP); Koji IKEBATA, Tokyo (JP); Kyoichi NAGATA, Tokyo (JP)

(73) Assignee: Elpida Memory, Inc., Tokyo (JP)

(21) Appl. No.: 13/888,637

(22) Filed: May 7, 2013

(30) Foreign Application Priority Data
May 7, 2012 (JP) 2012-105777

(51) Int. Cl. G11C 5/06

(52) U.S. Cl. CPC G11C 5/063
USPC 365/72

(57) ABSTRACT

Disclosed herein is a semiconductor device that includes a plurality of memory cells; a local bit line coupled to the memory cells; a global bit line; and a first switch circuit coupled between the global bit line and the local bit line, the first switch circuit electrically connecting the local bit line to the global bit line when at least one of first and second control signals is in an active state, and the first switch circuit electrically disconnecting the local bit line to the global bit line when both of the first and second control signals are in an inactive state.

### BACKGROUND OF THE INVENTION

1. Field of the Invention

The present invention relates to a semiconductor device, and more particularly relates to a semiconductor device including bit lines that are hierarchically structured.

2. Description of Related Art

Many semiconductor memory devices represented by a DRAM (Dynamic Random Access Memory) include a plurality of word lines extending in a row direction and a plurality of bit lines extending in a column direction. Memory cells are arranged in the intersections of the word lines and bit lines. When any of the word lines is selected, a memory cell allocated to the selected word line is connected to a corresponding bit line, and data held in the memory cell is read out to the bit line. The read data is amplified by a sense amplifier respectively connected to the bit lines.

However, in the above configuration, the sense amplifier needs to be provided for each of the bit lines or bit-line pairs, and thus there is a problem that the number of required sense amplifiers is increased as the integration degree of semiconductor memory devices becomes higher. As a method of solving such a problem, there is proposed a semiconductor memory device that uses hierarchically structured bit lines (see Japanese Patent Application Laid-open No. H8-195100).

The semiconductor memory device described in Japanese Patent Application Laid-open No. H8-195100 is hierarchized by lower local bit lines respectively connected to a plurality of memory cells and higher global bit lines respectively connected to a sense amplifier, and the number of required sense amplifiers is reduced by allocating a plurality of local bit lines to one global bit line. The connection of the global bit line and the local bit lines is made by a switch circuit connected between these lines.

Generally, when there is a defect in a word line or a bit line, the defective word line or the defective bit line is replaced by an auxiliary word line or an auxiliary bit line, thereby relieving the defect. However, when there is a defect in a control signal line that controls a switch circuit, because there is no auxiliary control signal line to relieve the defect, there is a problem that the whole chip becomes defective.

### SUMMARY

In one embodiment, there is provided a semiconductor device that includes: a plurality of memory cells; a local bit line coupled to the memory cells; a global bit line; and a first switch circuit coupled between the global bit line and the local bit line, the first switch circuit electrically connecting the local bit line to the global bit line when at least one of first and second control signals is in an active state, and the first switch circuit electrically disconnecting the local bit line to the global bit line when both of the first and second control signals are in an inactive state.

In another embodiment, there is provided a semiconductor device that includes: a plurality of memory cells; a first line coupled to the memory cells; a second line; a first transistor coupled between the first line and the second line; a first driver of which an output node is coupled to a gate of the first transistor; and a second driver of which an output node is coupled to the gate of the first transistor. The first and second drivers are arranged such that the first transistor is arranged between the first driver and the second driver.

According to the present invention, because a switch circuit that connects a global bit line and a local bit line has a redundant configuration, even when there is a defect in a control signal line that controls the switch circuit, it is possible to cause the switch circuit to function correctly.

### BRIEF DESCRIPTION OF THE DRAWINGS

FIG. 1 is a block diagram of a configuration of a semiconductor device according to an embodiment of the present invention;

FIG. 2 is a circuit diagram for specifically explaining the inside of the a memory cell array area according to a first embodiment of the present invention;

FIG. 3 is a block diagram indicative of an embodiment of a configuration of main parts in a row-system circuit shown in FIG. 1;

FIG. 4 is a circuit diagram indicative of an embodiment of a main switch driver shown in FIG. 2;

FIG. 5 is a circuit diagram indicative of an embodiment of a local switch driver shown in FIG. 2;

FIG. 6 is a circuit diagram indicative of an embodiment of a control-signal generation circuit included in a control circuit shown in FIG. 1;

FIG. 7 is a timing diagram for explaining an operation of the semiconductor device shown in FIG. 1;

FIG. 8 is a schematic diagram for explaining a layout of local control signal lines LSL0 and LSL1 and sub-word lines SWL0 to SWLn;

FIG. 9 is a circuit diagram for specifically explaining the inside of a memory cell array area according to a second embodiment of the present invention;

FIG. 10 is a circuit diagram for specifically explaining the inside of a memory cell array area according to a third embodiment of the present invention;

FIG. 11 is a circuit diagram for specifically explaining the inside of a memory cell array area according to a fourth embodiment of the present invention;

FIG. 12 is a circuit diagram indicative of an embodiment of a local precharge driver shown in FIG. 11;

FIG. 13 is a circuit diagram indicative of an embodiment of a local switch driver according to a fifth embodiment of the present invention; and

FIG. 14 is a block diagram indicative of an embodiment of a configuration of an information processing system according to a sixth embodiment of the present invention.

### DETAILED DESCRIPTION OF THE EMBODIMENTS

Preferred embodiments of the present invention will be explained below in detail with reference to the accompanying drawings.

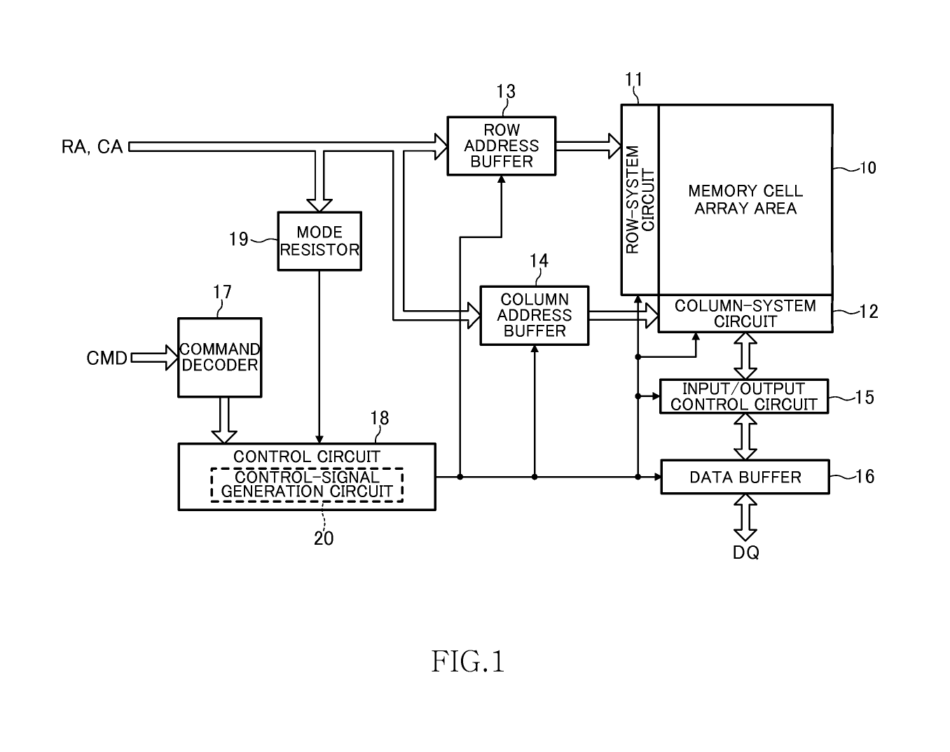

Referring now to FIG. 1, the semiconductor device according to the present embodiment is a DRAM (Dynamic Random Access Memory), and includes a memory cell array area 10. Although details thereof are explained later, in the memory cell array area 10, hierarchized main word lines and sub-word lines and hierarchized global bit lines and local bit lines are provided, and a memory cell is arranged in the intersections of the sub-word lines and the local bit lines. The selection of the main word lines and the sub-word lines is made by a row-system circuit 11, and the selection of the global bit lines and the local bit lines is made by a column-system circuit 12. A switch circuit (described later) is connected between the global bit lines and the local bit lines, and the control thereof is also executed by the row-system circuit 11.

A row address RA is supplied to the row-system circuit 11 through a row address buffer 13. A column address CA is supplied to the column-system circuit 12 through a column address buffer 14. Each of the row address RA and the column address CA is a signal supplied from outside, and whether these addresses are input to the row address buffer 13 or the column address buffer 14 is controlled by a control circuit 18. The control circuit 18 is a circuit that controls various types of functional blocks based on an output from a command decoder 17 that decodes an external command CMD. Specifically, when the external command CMD indicates an active command, the row address RA is supplied to the row address buffer 13. When the external command CMD indicates a read command or a write command, the column address CA is supplied to the column address buffer 14.

Therefore, when the active command and the read command are issued in this order and the row address RA and the column address CA are input in synchronization with these commands, data DQ can be read from a memory cell specified by these addresses. When the active command and the write command are issued in this order and the row address RA and the column address CA are input in synchronization with these commands, the data DQ can be written in a memory cell specified by these addresses. The read and write of the data DQ is performed through an input/output control circuit 15 and a data buffer 16.

Furthermore, a mode resistor 19 is provided in the semiconductor device according to the present embodiment, and a setting value thereof is supplied to the control circuit 18. A parameter indicating an operation mode of the semiconductor device according to the present embodiment is set in the mode resistor 19.

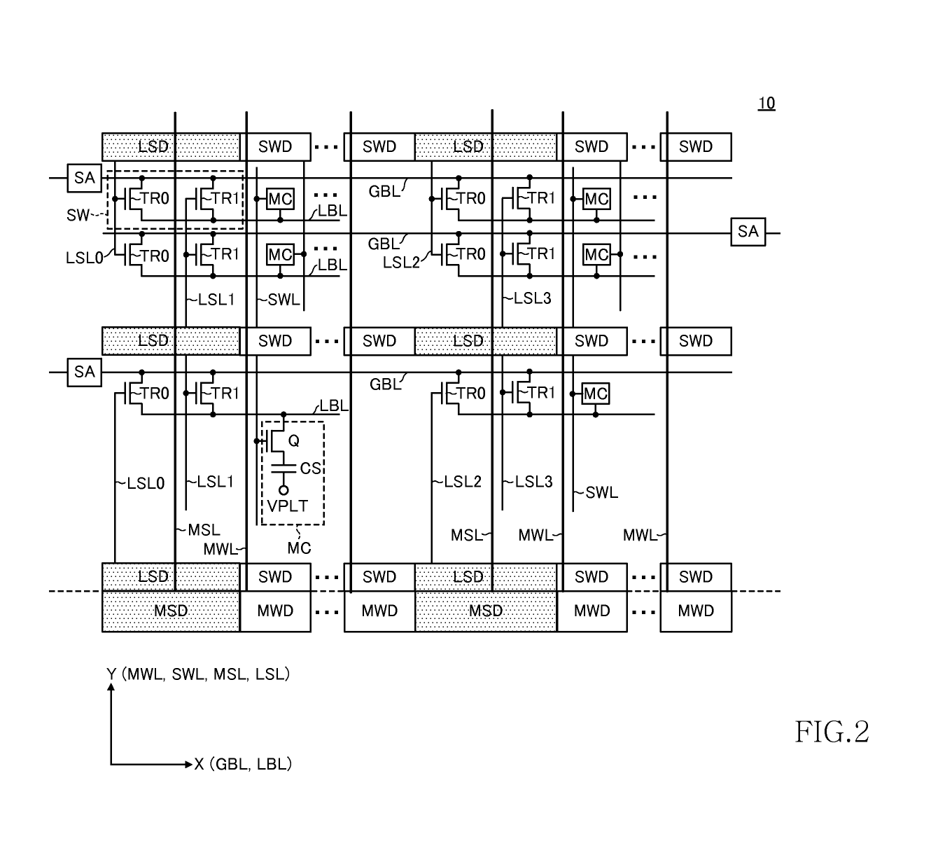

Turning to FIG. 2, a plurality of global bit lines GBL and a plurality of local bit lines LBL, both of which extend in an X direction, are arranged in the memory cell array area 10. The global bit lines GBL are hierarchically high-order bit lines and are connected to corresponding sense amplifiers SA, respectively. The local bit lines LBL are hierarchically low-order bit lines and are connected to memory cells MC. A switch circuit SW is connected between the global bit line GBL and the local bit line LBL.

The sense amplifier SA is a circuit that amplifies a potential difference appearing between a pair of global bit lines GBL. An operation timing of the sense amplifier SA is controlled by the control circuit 18 shown in FIG. 1. Although not shown in FIG. 2, the sense amplifier SA includes an equalizer circuit that equalizes potentials of the pair of global bit lines GBL. An operation of the equalizer circuit is controlled by an equalization signal (BLEQ), which is explained later. The equalization signal (BLEQ) is generated by the control circuit 18.

As shown in FIG. 2, a plurality of local bit lines LBL are allocated to each of the global bit lines GBL. This enables many memory cells MC to be allocated to one sense amplifier SA, thereby reducing the number of sense amplifiers SA. Each of the local bit lines LBL is connected to the global bit line GBL via the corresponding switch circuit SW. In the present embodiment, the switch circuit SW is constituted by two N-channel MOS transistors TR0 and TR1 and their gate electrodes are connected to corresponding local control signal lines LSL.

The local control signal lines LSL extend in Y direction, and is driven by the corresponding local switch drivers LSD. In the present embodiment, two transistors TR0 and TR1 constitute one switch circuit SW. A local control signal line LSL0 connected to the transistor TR0 is driven by a local switch driver LSD arranged on one side of a corresponding local bit line LBL. A local control signal line LSL1 connected to the transistor TR1 is driven by a local switch driver LSD arranged on the other side of the corresponding local bit line LBL. That is, the corresponding local bit lines LBL is arranged between these two local switch drivers LSD.

As described above, the semiconductor device 10 according to the present embodiment is a DRAM and thus each of the cells MC is constituted by a series circuit of a cell transistor Q and a cell capacitor CS. The cell transistor Q is constituted by an N-channel MOS transistor and has one end connected to the corresponding local bit line LBL and the other end connected to one end of the cell capacitor CS. A plate potential VPLT is supplied to the other end of the cell capacitor CS. A gate electrode of the cell transistor Q is connected to a corresponding sub-word line SWL. In the present specification, the sub-word line SWL may be also referred to simply as “word line”. The sub-word line SWL extends in a Y direction, and is driven by a corresponding sub-word driver SWD.

With this configuration, when one of the sub-word lines SWL is activated, the corresponding cell transistors Q are turned on, which causes the corresponding cell capacitors CS to be electrically connected to the local bit lines LBL. Accordingly, data stored in the cell capacitors CS are read out to the corresponding local bit lines LBL. In the present specification, the cell capacitor CS may be also referred to simply as “storage element”. It is not essential in the present invention that the cell capacitor constitutes the storage element. Another kind of element or a circuit constituted by a plurality of elements can be used therefor. Further, inclusion of the N-channel MOS transistor in the cell transistor Q is not essential in the present invention. Another element or a circuit constituted by a plurality of elements can be used therefor. In any case, a control terminal of the cell transistor Q (the gate electrode in the case of the MOS transistor) is connected to the corresponding sub-word line SWL.

The sub-word driver SWD is connected to a corresponding main word line MWL, which extends in a Y direction, and activated by a main word signal supplied through the main word line MWL. The main word signal is generated based on high-order bits of the row address RA. The activated sub-word driver SWD selects any of the sub-word lines SWL based on low-order bits of the row address RA. The main word signal is generated by a main word driver MWD, which is included in the row-system circuit 11 shown in FIG. 1.

The local switch driver LSD is connected to a corresponding main control signal line MSL, which extends in a Y direction, and activated by a main control signal supplied through the main control signal line MSL. The main control signal is also generated based on high-order bits of the row address RA. The activated local switch driver LSD turns on the corresponding switch circuit SW. The main control signal is generated by a main switch driver MSD, which is included in the row-system circuit 11 shown in FIG. 1.

In the present specification, respective lines and signals transferred by these lines may be denoted by like reference characters. For example, a main control signal transferred through the main control signal line MSL may be also referred to as “main control signal MSL”. Similarly, a local control signal transferred through the local control signal line LSL may be also referred to as “local control signal LSL”.

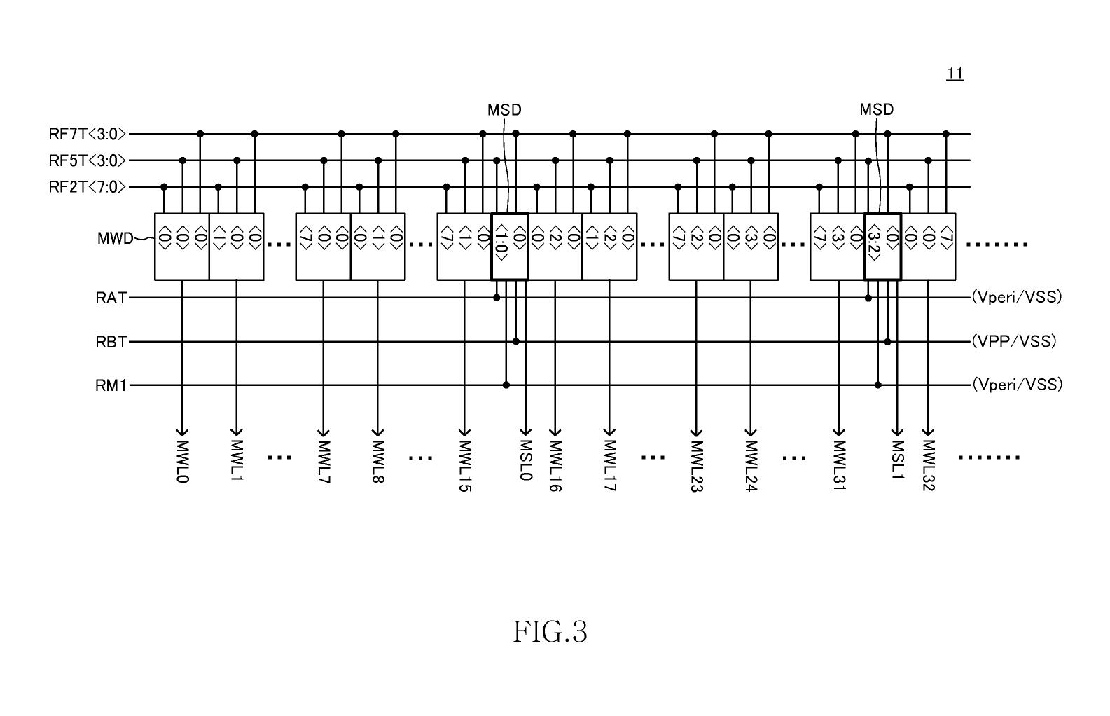

Turning to FIG. 3, a plurality of main word drivers MWD and a plurality of main switch drivers MSD are included in the row-system circuit 11. Pre-decode signals RF2T, RF5T, and RF7T are supplied to the main word driver MWD, and the pre-decode signals RF5T and RF7T are supplied to the main switch driver MSD. The pre-decode signal RF2T is an 8-bit signal that is generated by decoding bits A2 to A4 of the row address RA, and any one of the eight bits becomes an active level. Furthermore, the pre-decode signal RF5T is a 4-bit signal that is generated by decoding bits A5 and A6 of the row address RA, and any one of the four bits becomes an active level. Further, the pre-decode signal RF7T is a 4-bit signal that is generated by decoding bits A7 and A8 of the row address RA, and any one of the four bits becomes an active level.

In FIG. 3, three numbers among <0> to <7> denoted in the respective main word drivers MWD indicate selection of a signal regarding as to which bit in the respective pre-decode signals RF2T, RF5T, and RF7T is activated. As an example, the main word driver MWD denoted as <0>, <0>, <0> activates a corresponding main word signal MWL0 when the bit 0 in all of the pre-decode signals RF2T, RF5T, and RF7T is in an active level. The same holds true for the main switch driver MSD. As an example, the main switch driver MSD denoted as <1:0> and <0> activates a corresponding main control signal MSL0 when the bit 0 or the bit 1 in the pre-decode signal RF5T and the bit 0 in the pre-decode signal RF7T are in an active level. As shown in FIG. 3, timing signals RAT, RBT, and RM1 are supplied to the main switch driver MSD. These timing signals RAT, RBT, and RM1 are generated by a control-signal generation circuit 20 included in the control circuit 18. The circuit configuration of the control-signal generation circuit 20 is explained later.

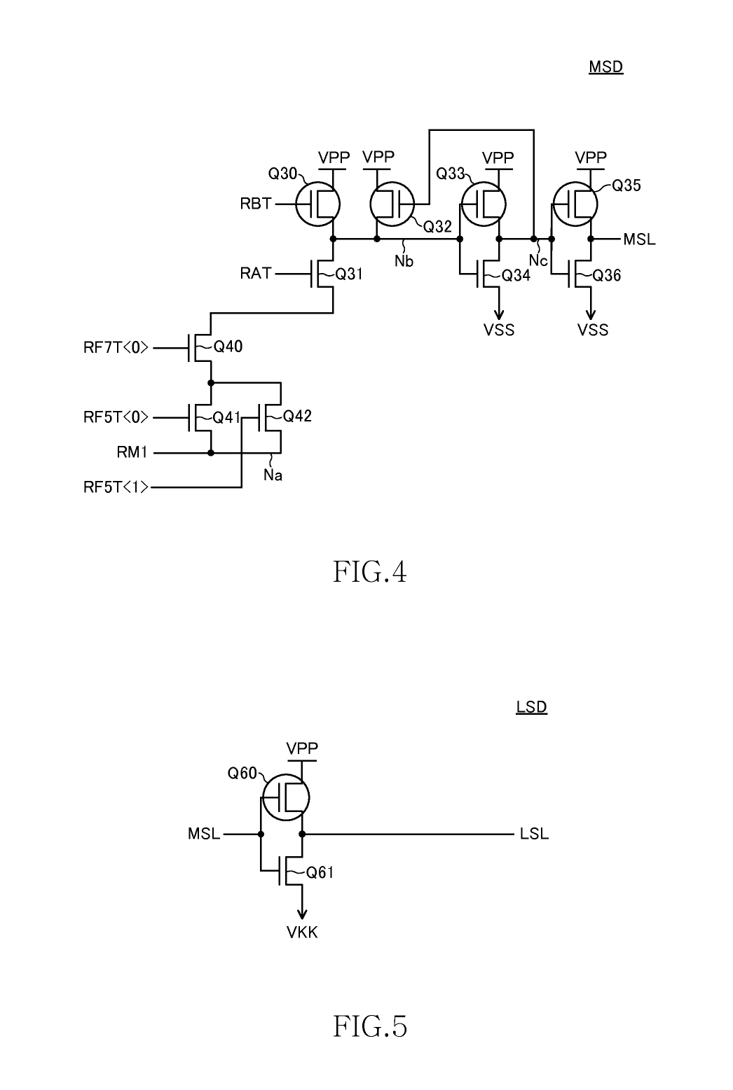

Turning to FIG. 4, this main switch driver MSD shown corresponds to the main switch driver MSD denoted as <1:0> and <0>.

As shown in FIG. 4, the main switch driver MSD includes N-channel MOS transistors Q31 and Q40 to Q42 that are connected between a signal node Na and a signal node Nb, and P-channel MOS transistors Q30 and Q32 that are connected in parallel between a power-supply node VPP and the signal node Nb. The signal node Na is a signal node to which the timing signal RM1 is supplied.

As shown in FIG. 4, the timing signal RBT is supplied to a gate electrode of the transistor Q30. With this configuration, in a time period when the timing signal RBT is at a low level, the signal node Nb is precharged at a high level. The logic level of the signal node Nb is output as the main control signal MSL through an inverter constituted by transistors Q33 and Q34 and an inverter constituted by transistors Q35 and Q36. As for the main control signal MSL, a low level is the active level and a high level is the inactive level. Furthermore, because a signal node Nc is connected to a gate electrode of the transistor Q32, when the main control signal MSL is inactivated at a high level, this state is maintained.

Meanwhile, the transistors Q31, Q40, and Q41 are connected in series, and the transistors Q41 and Q42 are connected in parallel. The timing signal RAT is supplied to a gate electrode of the transistor Q31, and the bit 0 in the pre-decode signal RF7T, the bit 0 in the pre-decode signal RF5T, and the bit 1 in the pre-decode signal RF5T are respectively supplied to gate electrodes of the transistors Q40 to Q42. With this configuration, after the signal node Nb is precharged at a high level, when the timing signal RAT is changed to a high level, the timing signal RM1 is changed to a low level, and the bit 0 or the bit 1 in the pre-decode signal RF5T and the bit 0 in the pre-decode signal RF7T become an active level, the signal node Nb is changed to a low level. When the signal node Nb is changed to a low level, the main control signal MSL is activated at a low level.

Turning to FIG. 5, the local switch driver LSD is an inverter circuit constituted by transistors Q60 and Q61. With this circuit configuration, when the main control signal MSL is activated at a low level, the local control signal LSL is activated at a VPP level. On the other hand, when the main control signal MSL is at a high level, the local control signal LSL is inactivated at a VKK level.

As shown in FIG. 2, the main control signal line MSL is connected to a plurality of local switch drivers LSD. Therefore, when a predetermined main control signal MSL is activated, all of the local switch drivers LSD connected to the main control signal line MSL are activated, thereby causing all of the corresponding switch circuits SW to be on an on-state. In this case, two transistors TR0 and TR1 constituting one switch circuit SW are controlled by the local switch drivers LSD that are respectively activated by the same main control signal MSL. This fact means that, when a certain main control signal MSL is activated, both of the two transistors TR0 and TR1 constituting one switch circuit SW are switched on. With this configuration, the switch circuit SW has a redundant configuration, and thus even when one of the local control signal lines LSL is disconnected, the global bit lines GBL and the local bit lines LBL can be correctly connected.

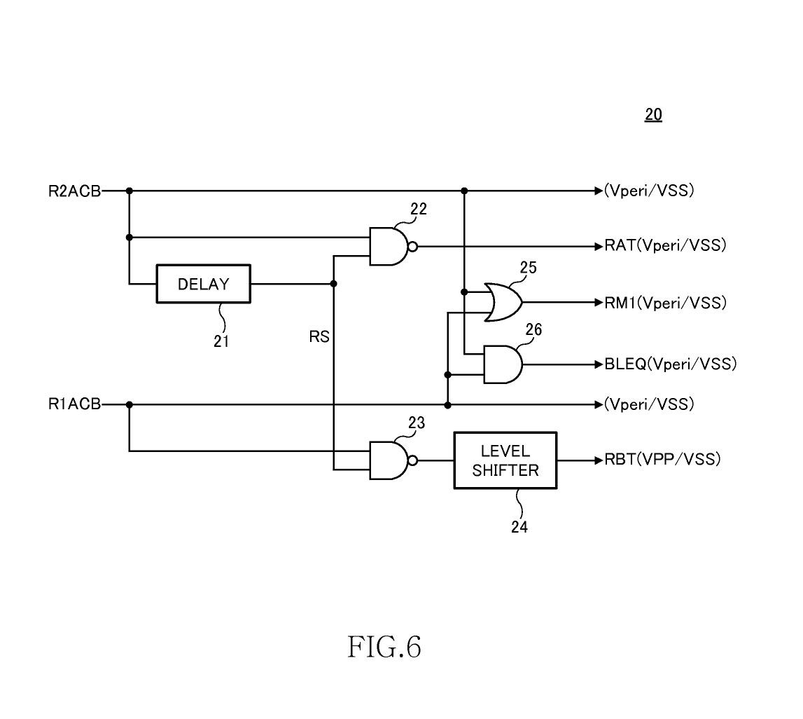

Turning to FIG. 6, the control-signal generation circuit 20 is a circuit that generates the timing signals RAT, RBT, and RM1 and the equalize signal BLEQ. The control-signal generation circuit 20 includes a delay circuit 21, NAND-gate circuits 22 and 23, a level shifter 24, an OR-gate circuit 25, and an AND-gate circuit 26. A timing signal R2ACB and a delay signal RS, which is generated by delaying the timing signal R2ACB by the delay circuit 21, are input to the NAND-gate circuit 22, and an output thereof is used as the timing signal RAT. Furthermore, a timing signal R1ACB and the delay signal RS are input to the NAND-gate circuit 23, and a signal generated by level-shifting an output thereof by the level shifter 24 is used as the timing signal RBT. The level shifter 24 has a function of amplifying an output signal of the NAND-gate circuit 23 from a VSS level to a VPP level. Signals other than the timing signal RBT has amplitude from the VSS level to a Vperi level.

The timing signals R1ACB and R2ACB are supplied to the OR-gate circuit 25, and an output thereof is used as the timing signal RM1. Further, the timing signals R1ACB and R2ACB are also supplied to the AND-gate circuit 26, and an output thereof is used as the equalize signal BLEQ. The timing signals R1ACB and R2ACB are signals activated in this order by responding to an active command.

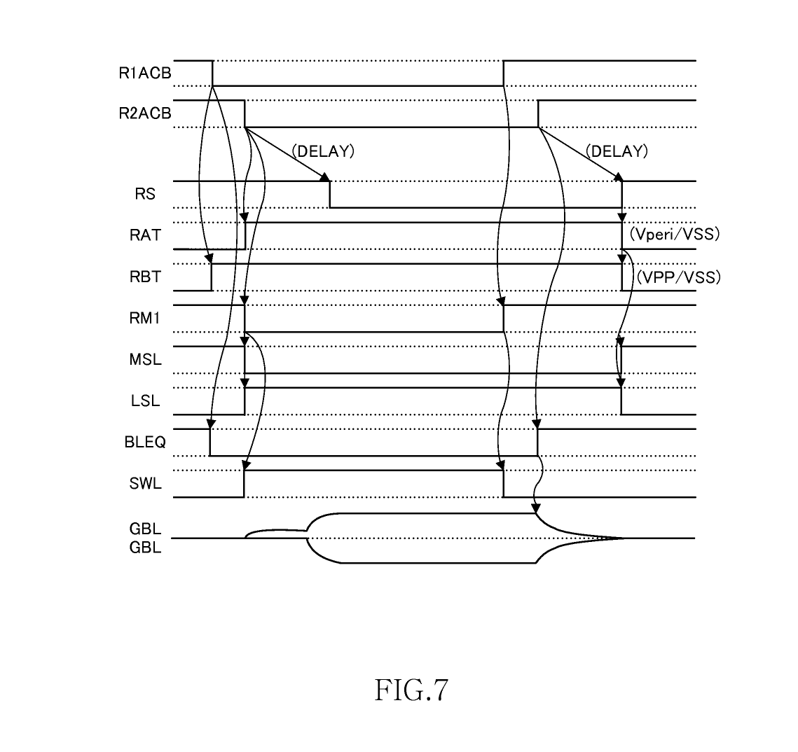

Turning to FIG. 7, first, in a state before an active command is issued from outside, both of the timing signals RAT and RBT are at a low level. Therefore, the signal node Nb in the main switch driver MSD shown in FIG. 4 is precharged at a high level. In addition, the equalize signal BLEQ is maintained at a high level, and thus a pair of the global bit lines GBL is precharged at the same potential.

Thereafter, when an active command is issued from outside, the timing signals R1ACB and R2ACB are activated in this order in the control circuit 18. With response thereto, the control-signal generation circuit 20 activates the timing signal RBT, and then activates the timing signals RAT and RM1. With this process, the precharged state of the main switch driver MSD is cancelled, and thus the main switch driver MSD selected based on the pre-decode signals RF5T and RF7T activates the corresponding main control signal MSL at a low level. As a result, all of the local switch drivers LSD connected to the main control signal line MSL are activated, and the corresponding switch circuit SW is switched on. Furthermore, because the equalize signal BLEQ changes to a low level due to the activation of the timing signal R1ACB, the precharged state of the pair of the global bit lines GBL is cancelled.

The timing signal RM1 is used also as an activation signal for the sub-word driver SWD. Therefore, when the timing signal RM1 is activated, a sub-word line SWL selected by the row address RA is activated. Accordingly, data is read from a corresponding memory cell MC, and the potential of the local bit line LBL is changed. This change is transmitted to the global bit line GBL through the switch circuit SW, and a potential difference is generated between a pair of the global bit lines. Thereafter, the sense amplifier SA is activated at a predetermined timing, and the potential difference between these global bit lines is amplified.

Although not shown in the drawings, subsequently, when the column address CA is input with a read command, the sense amplifier SA is selected by the column-system circuit 12 based on the column address CA. The data DQ read from the selected sense amplifier SA is output to outside through the input/output control circuit 15 and the data buffer 16. When a precharge command is issued, the timing signals R1ACB and R2ACB are inactivated in this order and shift to an original precharge state.

In the operations described above, when a predetermined main control signal MSL is activated, the two transistors TR0 and TR1 included in the same switch circuit SW are commonly controlled through the two local control signal lines LSL0 and LSL1. Accordingly, even when one of the local control signal lines LSL0 and LSL1 is disconnected, one of the transistors TR0 and TR1 can be correctly controlled through the other one of the local control signal lines.

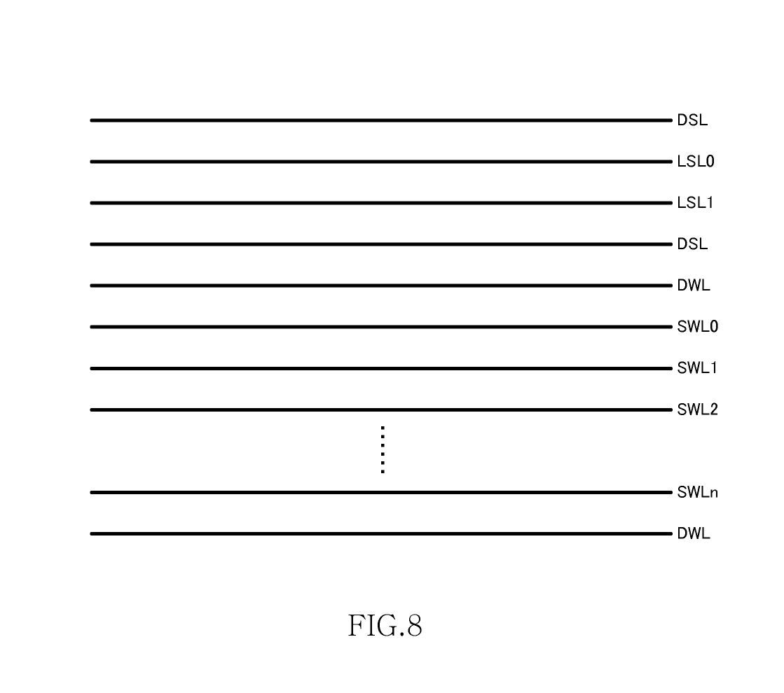

Meanwhile, when there is a short-circuit fault in any one or both of the local control signal lines LSL0 and LSL1, there are cases where a normal operation can be performed or cannot be performed, depending on which one the short-circuited line is. For example, when any one of the local control signal lines LSL0 and LSL1 is short-circuited to a VPP line, a corresponding transistor is switched on constantly, and thus a normal operation cannot be performed at all. To avoid such a problem, as shown in FIG. 8, it is preferred that the local control signal lines LSL0 and LSL1 are sandwiched by dummy lines that are in a floating state.

In the example shown in FIG. 8, the local control signal lines LSL0 and LSL1 and sub-word lines SWL0 to SWLn are formed in the same wiring layer, and a dummy line DSL is arranged on each side of the local control signal lines LSL0 and LSL1 and a dummy line DWL is arranged on each side of the sub-word lines SWL0 to SWLn. In a pattern in which many lines are repeatedly and regularly arranged, a defect tends to occur in a line at an end part, and thus, in the example shown in FIG. 8, the dummy lines DSL and DWL are arranged on the end parts, respectively. As the dummy line DSL is set to be in a floating state, even when there is a short-circuit fault between any one or both of the local control signal lines LSL0 and LSL1 and the dummy line DSL, the switch circuit SW can be correctly operated.

As explained above, in the semiconductor device according to the first embodiment, the switch circuit SW has a redundant configuration. Therefore, even when there is a disconnection or a short-circuit fault in one of the local control signal lines LSL, the global bit lines GBL and the local bit lines LBL can be correctly connected. In other words, as far as at least one of the local control signals LSL0 and LSL1 is in an active state, the global bit lines GBL and the local bit lines LBL can be correctly connected. Furthermore, in the first embodiment, because the two transistors TR0 and TR1 are included in the switch circuit SW, even when there is a defect in one of the transistors itself, the semiconductor device can be correctly operated.

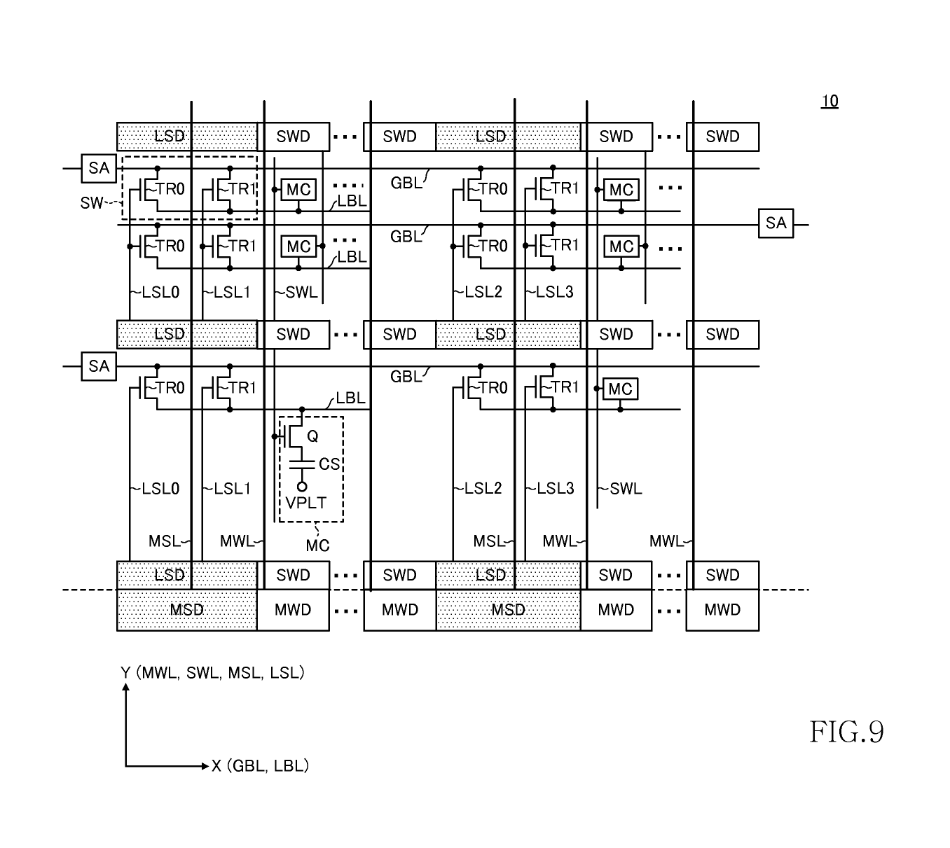

Turning to FIG. 9, the second embodiment is different from the first embodiment shown in FIG. 2 in a feature that the local control signal lines LSL0 and LSL1 allocated to the same switch circuit SW are driven by the local switch drivers LSD that are arranged on one side of a corresponding local bit line LBL. Other features of the second embodiment are identical to those of the first embodiment shown in FIG. 2. Therefore, like elements are denoted by like reference characters and redundant explanations thereof will be omitted. Also in the configuration of the second embodiment, effects identical to those of the first embodiment can be achieved.

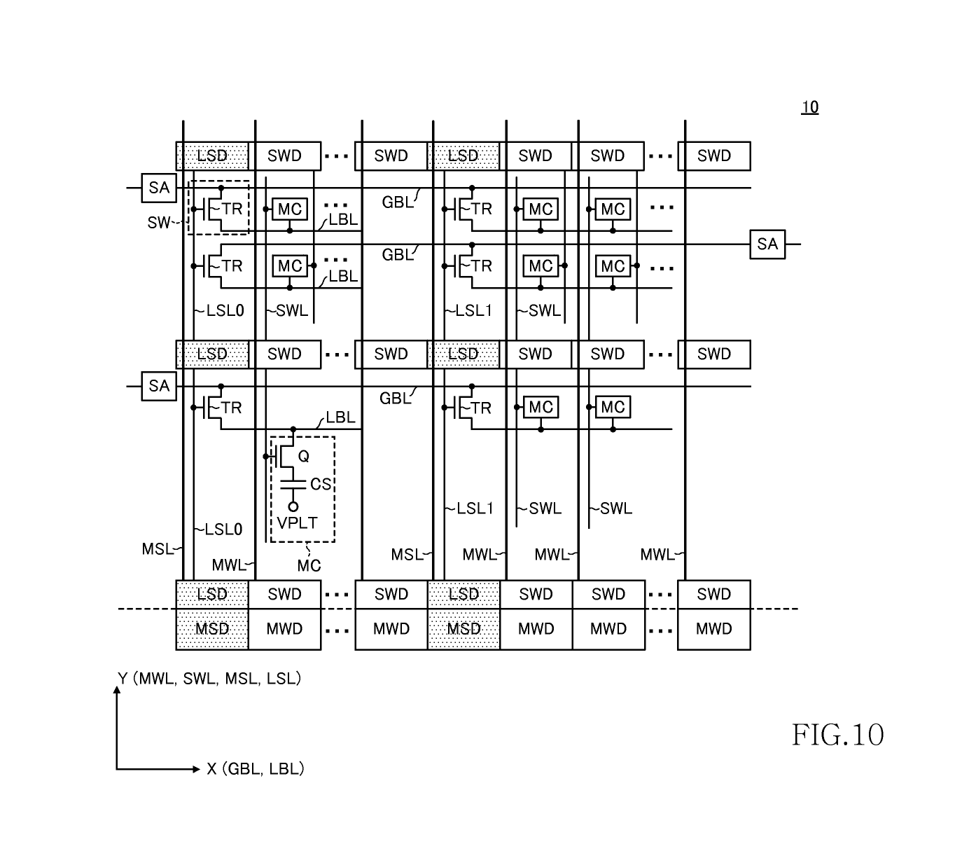

Turning to FIG. 10, in the third embodiment, the switch circuit SW is constituted by one transistor TR. However, a local control signal line LSL connected to a gate electrode of the transistor TR are commonly driven by two local switch drivers LSD arranged on both sides of the local control signal line LSL. In other words, the third embodiment has a configuration in which an end part of the local control signal line LSL that is driven by one of the local switch drivers LSD and another end part of the local control signal line LSL that is driven by the other one of the local switch drivers LSD are connected to a gate electrode of the transistor TR. Other features of the third embodiment are identical to those of the first embodiment shown in FIG. 2. Therefore, like elements are denoted by like reference characters and redundant explanations thereof will be omitted.

Also in the above configuration, effects identical to those of the first embodiment can be achieved. Furthermore, in the third embodiment, the switch circuit SW is constituted by one transistor TR. Therefore, the number of required elements is reduced, and the number of the local control signal lines LSL can be made half as compared to the first and second embodiments.

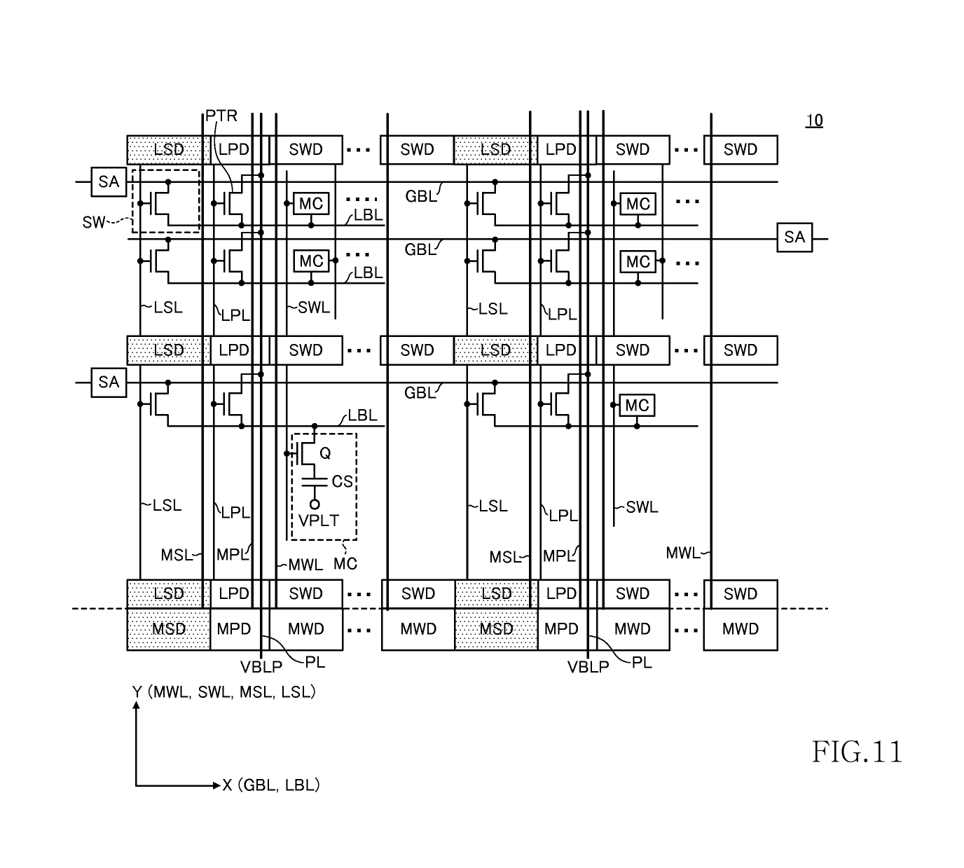

Turning to FIG. 11, the fourth embodiment is different from the third embodiment in a feature that the fourth embodiment includes a precharge line PL that precharges the local bit line LBL to have a midpoint potential VBLP. The precharge line PL is connected to the local bit line LBL through a precharge transistor PTR. Therefore, when the precharge transistor PTR is switched on, the local bit line

LBL is precharged to have the midpoint potential VBLP. In the first to third embodiments, a circuit that directly precharges the local bit line LBL to have the midpoint potential VBLP is not provided, and therefore precharging of the local bit line LBL needs to be performed through the global bit line GBL. On the other hand, in the fourth embodiment, because the local bit line LBL can be directly precharged to have the midpoint potential VBLP, the precharging speed can be made faster.

The control of the precharge transistor PTR is executed by hierarchized main precharge signal lines MPL and local precharge signal lines LPL. The relationship between the main precharge signal line MPL and the local precharge signal line LPL is identical to the relationship between the main control signal line MSL and the local control signal line LSL. That is, when a predetermined main precharge signal MPL is activated by a main precharge driver MPD, all of local precharge drivers LPD corresponding to the main precharge driver MPD are activated.

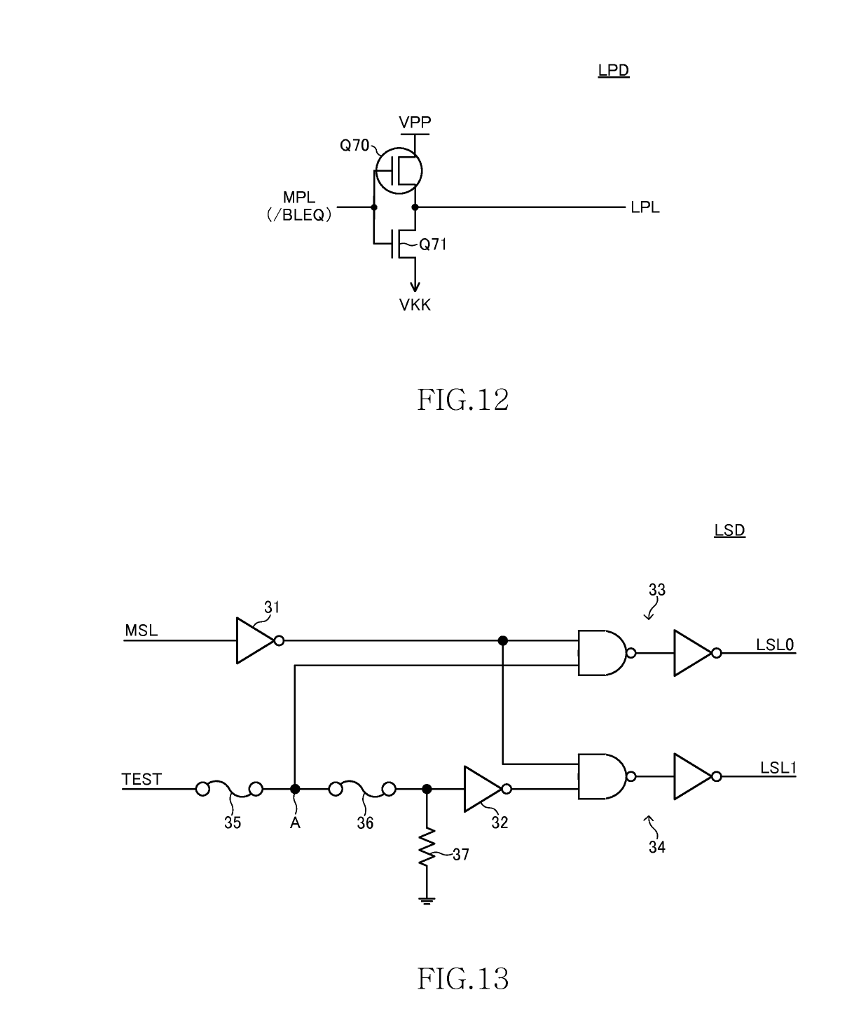

Turning to FIG. 12, the local precharge driver LPD is an inverter circuit constituted by transistors Q70 and Q71. With this circuit configuration, when the main precharge signal MPL is activated at a low level, the local precharge signal LPL is activated at a VPP level. An inversion signal of the equalize signal BLEQ can be used as the main precharge signal MPL.

In the fourth embodiment, one local precharge signal line LPL is commonly driven by two local precharge drivers LPD arranged on both sides of the local precharge signal line LPL. In other words, an end part of the local precharge signal line LPL that is driven by one of the local precharge drivers LPD and another end part of the local precharge signal line LPL that is driven by the other one of the local precharge drivers LPD are connected to a gate electrode of the corresponding precharge transistor PTR. Other features of the fourth embodiment are identical to those of the third embodiment shown in FIG. 10. Therefore, like elements are denoted by like reference characters and redundant explanations thereof will be omitted.

With the above configuration, the local bit lines LBL can be quickly precharged, and even when the local precharge signal line LPL is disconnected, the precharge transistor PTR can be switched correctly.

Turning to FIG. 13, the local switch driver LSD according to the fifth embodiment can selectively activate two local control signals LSL0 and LSL1 relative to one main control signal MSL. To specifically explain, the local switch driver LSD according to the fifth embodiment includes inverters 31 and 32, AND-gate circuits 33 and 34, fuse elements 35 and 36, and a resistor 37. The AND-gate circuit 33 receives a main control signal MSL inverted by the inverter 31 and a potential of a connection node A of the fuse elements 35 and 36, and the local control signal LSL0 is output from an output node thereof. The AND-gate circuit 34 receives the main control signal MSL inverted by the inverter 31 and an output signal of the inverter 32, and the local control signal LSL1 is output from an output node thereof. An input node of the inverter 32 is grounded through the resistor 37, and is connected to the connection node A through the fuse element 36.

As shown in FIG. 13, a test signal TEST is input to an end of the fuse element 35. The test signal TEST is a signal for selecting the local control signal lines LSL0 and LSL1 to be used, and when the test signal TEST is set to be a high level, the local control signal line LSL0 is selected, and when it is set to be a low level, the local control signal line LSL1 is selected. Therefore, when an operation test is conducted while setting the test signal TEST to be a high level and a low level, it is possible to determine whether the local control signal lines LSL0 and LSL1 have any defect.

As a result of the determination, when the local control signal line LSL0 is confirmed to be normal, the test signal TEST is fixed to a high level in a normal operation. With this process, because only the local control signal line LSL0 is used, it becomes possible to reduce a consumption current generated due to charging and discharging of the local control signal line LSL1. Furthermore, as a result of the determination, when the local control signal line LSL1 is confirmed to be normal, the fuse element 35 is cut off. With this process, because only the local control signal line LSL1 is used, it becomes possible to reduce a consumption current generated due to charging and discharging of the local control signal line LSL0.

Furthermore, in a case where the local control signal lines LSL0 and LSL1 are short-circuited each other, the fuse element 36 is cut off and the test signal TEST is fixed to a high level in a normal operation. With this process, because both of the local control signal lines LSL0 and LSL1 are used, a normal operation can be achieved.

As the fuse elements 35 and 36, it is possible to use an optical fuse element that can be cut off by irradiation of a laser beam, and also possible to use a fuse circuit including an anti-fuse element that can store therein information by insulation breakdown due to application of a high voltage. The fuse circuit using an anti-fuse element has a characteristic such that an occupied area on a chip is small.

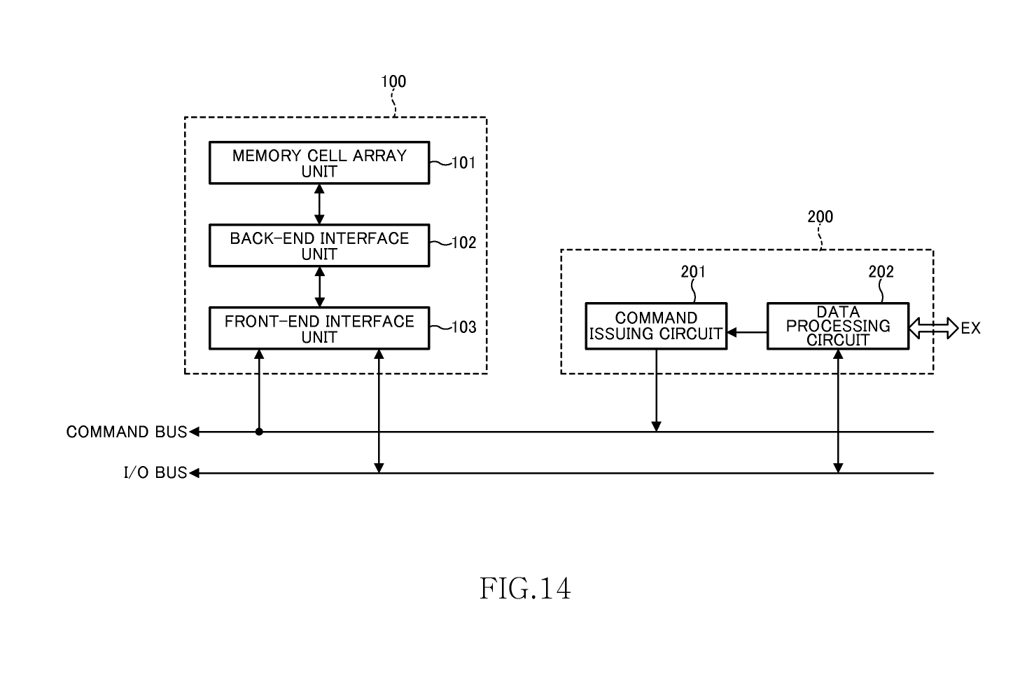

Turning to FIG. 14, the information processing system according to the sixth embodiment includes a semiconductor device 100 having the configuration disclosed in each of the above embodiments and includes a controller 200 that controls operations of the semiconductor device 100. The semiconductor device 100 includes a memory cell array unit 101, a back-end interface unit 102, and a front-end interface unit 103. The memory cell array unit 101 includes the memory cell array area 10 shown in FIG. 1. The back-end interface unit 102 includes a peripheral circuit group of the memory cell array area 10, such as the row-system circuit 11 and the column-system circuit 12. The front-end interface unit 103 has a function of performing communication with the controller 200 via a command bus and an I/O bus. Although only one semiconductor device 100 is shown in FIG. 14, a plurality of semiconductor devices 100 can be connected to the command bus and the I/O bus.

The controller 200 includes a command issuing circuit 201 and a data processing circuit 202, and controls operations of the entire system and operations of the semiconductor device 100. The controller 200 controls operations of the entire system while being connected to the command bus and the I/O bus in the system, and has an interface function to outside EX of the system. The command issuing circuit 201 issues the command CMD to the semiconductor device 100 via the command bus. The data processing circuit 202 transmits and receives the data DQ between the semiconductor device 100 via the I/O bus, and performs processes necessary for controlling the operations of the information processing system. It is also possible that the semiconductor device 100 according to the sixth embodiment is included in the controller 200 itself shown in FIG. 14.

The information processing system shown in FIG. 14 is, for example, a system to be incorporated in an electronic device, and the information processing system can be incorporated in devices such as personal computers, communication electronic devices, electronic devices of a mobile unit such as a car, electronic devices used in other industrial fields, and electronic devices used in consumer products.

It is apparent that the present invention is not limited to the above embodiments, but may be modified and changed without departing from the scope and spirit of the invention.

As an example, the above embodiments have explained a case where the present invention is applied to a DRAM; however, the application target of the present invention is not limited to DRAMS. Therefore, it is possible to apply the present invention to other types of semiconductor memory devices such as an SRAM, a flash memory, and a ReRAM, and it is also possible to apply the present invention to logic semiconductor devices that have memory cell arrays incorporated therein.

What is claimed is:

1. A semiconductor device comprising:
a plurality of memory cells;
a local bit line coupled to the memory cells;
a global bit line; and
a first switch circuit coupled between the global bit line and the local bit line, the first switch circuit electrically connecting the local bit line to the global bit line when at least one of first and second control signals is in an active state, and the first switch circuit electrically disconnecting the local bit line to the global bit line when both of the first and second control signals are in an inactive state.

2. The semiconductor device as claimed in claim 1, further comprising first and second switch drivers respectively generating the first and second control signals.

3. The semiconductor device as claimed in claim 2, wherein the first and second switch drivers are commonly controlled based on a third control signal.

4. The semiconductor device as claimed in claim 2, wherein the first switch circuit includes first and second transistors coupled in parallel between the global bit line and the local bit line, and the first and second control signals are respectively supplied to control electrodes of the first and second transistors.

5. The semiconductor device as claimed in claim 2, wherein the first switch circuit includes a third transistor coupled between the global bit line and the local bit line, and the first and second control signals are commonly supplied to a control electrode of the third transistor.

6. The semiconductor device as claimed in claim 4, wherein the local bit line is arranged between the first and second switch drivers.

7. The semiconductor device as claimed in claim 4, wherein both of the first and second switch drivers are arranged on one side of the local bit line.

8. The semiconductor device as claimed in claim 1, further comprising:
a precharge line supplied with a predetermined potential; and
a second switch circuit coupled between the precharge line and the local bit line, the second switch circuit electrically connecting the local bit line to the precharge line when at least one of fourth and fifth control signals is in an active state, and the second switch circuit electrically disconnecting the local bit line to the precharge line when both of the fourth and fifth control signals are in an inactive state.

9. The semiconductor device as claimed in claim 1, further comprising:
a plurality of word lines; and
first and second control signal lines respectively transferring the first and second control signals, wherein
each of the memory cells includes a memory element and a cell transistor connected in series,
each of the word lines is coupled to a control electrode of an associated one of the cell transistors, and
the word lines and the first and second control signal lines are provided on a predetermined wiring layer.

10. The semiconductor device as claimed in claim 9, further comprising first and second dummy lines provided on the predetermined wiring layer,
wherein the first and second control signal lines are arranged between the first and second dummy lines.

11. The semiconductor device as claimed in claim 10, wherein the first and second dummy lines are in a floating state.

12. A semiconductor device comprising:
a plurality of memory cells;
a first line coupled to the memory cells;
a second line;
a first transistor coupled between the first line and the second line;
a first driver of which an output node is coupled to a gate of the first transistor; and
a second driver of which an output node is coupled to the gate of the first transistor;
the first and second drivers being arranged such that the first transistor is arranged between the first driver and the second driver.

13. The semiconductor device as claimed in claim 12, further comprising a control signal line coupled to both input nodes of the first and second drivers.

14. The semiconductor device as claimed in claim 12, further comprising:
a plurality of additional memory cells;
a third line coupled to the additional memory cells;
a fourth line;
a second transistor coupled between the third line and the fourth line; and
a third driver of which an output node is coupled to a gate of the second transistor, the third driver being arranged such that the second transistor is arranged between the second and third drivers.

15. The semiconductor device as claimed in claim 14, further comprising a control signal line coupled to each of input nodes of the first, second and third drivers.

16. The semiconductor device as claimed in claim 14, wherein the gate of the second transistor is coupled to the output node of the third driver.

17. The semiconductor device as claimed in claim 12, further comprising:
a fifth line supplied with a voltage;
a third transistor coupled between the first line and the fifth line;
a fourth driver of which an output node is coupled to a gate of the third transistor; and
a fifth driver of which an output node is coupled to the gate of the third transistor;
the fourth and fifth drivers being arranged such that the third transistor is arranged between the fourth driver and the fifth driver.

18. The semiconductor device as claimed in claim 17, wherein the first driver is arranged adjacently to the fourth driver and the second driver is arranged adjacently to the fifth driver.

19. The semiconductor device as claimed in claim 17, wherein the first and third transistors are arranged adjacently to each other.
